(19) United States
(12) Patent Application Publication
(10) Pub. No.: US 2024/0356469 A1
(43) Pub. Date: Oct. 24, 2024

(54) DETECTION METHOD AND APPARATUS FOR MOTOR PARAMETERS

(71) Applicant: Carrier Corporation, Palm Beach Gardens, FL (US)

(72) Inventors: Kun Chen, Shanghai (CN); Zhenyu Zhang, Shanghai (CN); Ismail Agirman, Palm Beach Gardens, FL (US)

(21) Appl. No.: 18/641,874

(22) Filed: Apr. 22, 2024

(30) Foreign Application Priority Data
Apr. 23, 2023 (CN) CN202310443919.7

(51) Int. Cl. H02P 21/14; H02P 21/22; H02P 23/10; H02P 25/024

(52) U.S. Cl. CPC H02P 21/141; H02P 21/22; H02P 23/10; H02P 25/024

(57) ABSTRACT

Disclosed is a method for detecting motor parameters, comprising: injecting a first direct current signal; receiving a first d-q axis feedback current corresponding to the first direct current signal and a first d-q axis voltage output by a current regulation module; injecting a second direct current signal different from the first direct current signal; receiving a second d-q axis feedback current corresponding to the second direct current signal and a second d-q axis voltage output by the current regulation module; and determining motor parameters based on the first d-q axis feedback current, the first d-q axis voltage, the second d-q axis feedback current and the second d-q axis voltage. Also disclosed is an apparatus for detecting motor parameters, a computer program product and an air conditioner compressor system.

### CROSS REFERENCE TO RELATED APPLICATIONS

This application claims priority to Chinese Patent Application No. CN202310443919.7 filed on Apr. 23, 2023, which is incorporated by reference herein in its entirety.

### FIELD OF THE INVENTION

The application relates to the field of motor parameter detection, and more specifically, to a method for detecting motor parameters, an apparatus for detecting motor parameters, a computer program product, and an air-conditioning compressor system.

### BACKGROUND

The motor used in the inverter air conditioner industry is a permanent magnet synchronous motor (referred to as PMSM), and the control algorithm of the permanent magnet synchronous motor is generally a vector control algorithm, that is, a field-oriented control algorithm (referred to as FOC). The vector control algorithm can be composed of coordinate transformation, current sampling and reconstruction, position estimation, speed loop regulator, current loop regulator, and space vector modulation (SVPWM for short), for example.

The accuracy of PMSM parameters will directly determine the performance and stability of vector control. But in most PMSM-driven applications, the motor parameters are unknown and will change with age. The existing methods for detecting motor parameters need to rotate the rotor and use complex algorithms to detect parameters, which is inconvenient to operate.

### SUMMARY OF THE INVENTION

According to a first aspect, a method for detecting motor parameters is provided. The method comprises: injecting a first direct current signal; receiving a first d-q axis feedback current corresponding to the first direct current signal and a first d-q axis voltage output by a current regulation module; injecting a second direct current signal different from the first direct current signal; receiving a second d-q axis feedback current corresponding to the second direct current signal and a second d-q axis voltage output by the current regulation module; and determining motor parameters based on the first d-q axis feedback current, the first d-q axis voltage, the second d-q axis feedback current and the second d-q axis voltage.

Optionally, the motor is a permanent magnet synchronous motor and the current regulation module is a PI controller.

Optionally, both the first direct current signal and the second direct current signal are positive currents on the d-axis.

Optionally, the motor parameters include a stator resistance Rₛ, wherein the stator resistance Rₛ is determined according to the following formula:

$${R}_{s} = \frac{{V}_{dc 1} - {V}_{dc 2}}{{i}_{dc 1} - {i}_{dc 2}} ,$$

wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}. Optionally, the motor parameters include permanent magnet flux linkage λₘ, wherein the permanent magnet flux linkage λₘ is determined according to the following formula:

$${λ}_{m} = \frac{{V}_{rated} - {I}_{rated} * {R}_{s}}{2 * π * {f}_{rated}} ,$$

wherein V_{rated} is a rated voltage of the permanent magnet synchronous motor, I_{rated} is a rated current of the permanent magnet synchronous motor, and f_{rated} is a rated frequency of the permanent magnet synchronous motor.

Optionally, the above method also comprises: injecting a third signal, the third signal being a sinusoidal signal with a certain frequency and amplitude applied on the d-axis; receiving a third d-axis voltage output by the current regulation module, the third d-axis voltage being corresponding to the third signal; and determining a d-axis inductance L_{d} according to the third d-axis voltage.

Optionally, the third signal is represented by the following formula: i_{hd}=i_{d}+iₕ₁ sin (2*π*fₕ₁*t), wherein i_{hd} is the third signal, i_{d} is a DC offset on the d-axis, iₕ₁ is an amplitude of the sinusoidal signal, and fₕ₁ is a frequency of the sinusoidal signal.

Optionally, the d-axis inductance Ld is determined according to the following formula:

$${L}_{d} = \frac{{V}_{hd}}{2 ⋆ π ⋆ {f}_{h 1} ⋆ {i}_{h 1}} ,$$

wherein V_{hd} is the third d-axis voltage.

Optionally, the above method also comprises: injecting a fourth signal, the fourth signal being a sinusoidal signal with a certain frequency and amplitude applied on the q-axis; receiving a fourth q-axis voltage output by the current regulation module, the fourth q-axis voltage being corresponding to the fourth signal; and determining a q-axis inductance L_{q} according to the fourth q-axis voltage, wherein the fourth signal is represented by the following formula: i_{hq}=iₕ₂ sin (2*π*fₕ₂*t), wherein i_{hq} is the fourth signal, iₕ₂ is an amplitude of the sinusoidal signal, and fₕ₂ is a frequency of the sinusoidal signal, wherein the q-axis inductance L_{q} is determined according to the following formula:

$${L}_{q} = \frac{{V}_{hq}}{2 * π * {f}_{h 2} * {i}_{h 2}} ,$$

wherein V_{hq} is the fourth q-axis voltage.

An apparatus for detecting motor parameters is also disclosed. The apparatus comprises: a first receiving device for receiving a first d-q axis feedback current corresponding to an injected first direct current signal and a first d-q axis voltage output by a current regulation module; a second receiving device for receiving a second d-q axis feedback current corresponding to an injected second direct current signal and a second d-q axis voltage output by the current regulation module; and a determining device for determining the motor parameters based on the first d-q axis feedback current, the first d-q axis voltage, the second d-q axis feedback current and the second d-q axis voltage. The apparatus may be termed a motor parameter detection apparatus. The apparatus may be configured to detect motor parameters.

Optionally, the motor is a permanent magnet synchronous motor and the current regulation module is a PI controller, and both the first direct current signal and the second direct current signal are positive currents on the d-axis.

Optionally, the motor parameters include a stator resistance Rₛ, wherein the determining device is configured to determine the stator resistance Rₛ according to the following formula: Rₛ=V_{dc1}−V_{dc2}/i_{dc1}−i_{dc2}, wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}.

Optionally, the motor parameters include permanent magnet flux linkage λₘ, wherein the determining device is configured to determine the permanent magnet flux linkage λₘ according to the following formula:

$${λ}_{m} = \frac{{V}_{rated} - {I}_{rated} * {R}_{s}}{2 * π * {f}_{rated}} ,$$

wherein V_{rated} is a rated voltage of the permanent magnet synchronous motor, I_{rated} is a rated current of the permanent magnet synchronous motor, and f_{rated} is a rated frequency of the permanent magnet synchronous motor.

Optionally, the above apparatus further comprises: a third receiving device for receiving a third d-axis voltage output by the current regulation module, the third d-axis voltage being corresponding to the third signal which is a sinusoidal signal with a certain frequency and amplitude applied on the d-axis; and the determining device is also configured to determine a d-axis inductance La according to the third d-axis voltage.

Optionally, the third signal is represented by the following formula: i_{hd}=i_{d}+iₕ₁ sin (2*π*fₕ₁*t), wherein i_{hd} is the third signal, i_{d} is a DC offset on the d-axis, iₕ₁ is an amplitude of the sinusoidal signal, and fₕ₁ is a frequency of the sinusoidal signal, and wherein the determining device is further configured to determine the d-axis inductance L_{d} according to the following formula:

$${L}_{d} = \frac{{V}_{hd}}{2 * π * {f}_{h 1} * {i}_{h 1}} ,$$

wherein V_{hd} is the third d-axis voltage.

Optionally, the above apparatus further comprises: a fourth receiving device for receiving a fourth q-axis voltage output by the current regulation module, the fourth q-axis voltage being corresponding to an injected fourth signal which is a sinusoidal signal with a certain frequency and amplitude applied on the q-axis; and the determining device is further configured to determine a q-axis inductance L_{q} according to the fourth q-axis voltage, wherein the fourth signal is represented by the following formula: I_{hq}=iₕ₂ sin (2*π*fₕ₂*t), wherein i_{hq} is the fourth signal, iₕ₂ is an amplitude of the sinusoidal signal, and fₕ₂ is a frequency of the sinusoidal signal, wherein the q-axis inductance L_{q} is determined according to the following formula:

$${L}_{q} = \frac{{V}_{hq}}{2 * π * {f}_{h 2} * {i}_{h 2}} ,$$

wherein V_{hq} is the fourth q-axis voltage.

A computer program product comprising a computer program is also disclosed, wherein the computer program is executed by a processor, the method described above, including any of the optional features, is implemented.

An air-conditioning compressor system is also disclosed. The system comprises a permanent magnet synchronous motor; and the apparatus described above for detecting motor parameters of the permanent magnet synchronous motor, wherein the apparatus may include any of the optional features.

### BRIEF DESCRIPTION OF THE DRAWINGS

The above and other objects and advantages of the method and apparatus will be more fully understood from the following detailed description in conjunction with the accompanying drawings, wherein the same or similar elements are denoted by the same reference numerals.

FIG. 1 shows a schematic flow chart of a method for detecting motor parameters;

FIG. 2 shows a schematic structural diagram of an apparatus for detecting motor parameters;

FIG. 3 shows a schematic diagram of injecting signals into a system including an apparatus for detecting motor parameters;

FIG. 4 shows a waveform diagram of a signal injected into the d-q axis; and

FIG. 5 shows a d-q axis equivalent circuit diagram of a permanent magnet synchronous motor.

### DETAILED DESCRIPTION OF THE INVENTION

The invention is described more fully hereinafter with reference to the accompanying drawings, in which illustrative embodiments of the invention are shown. However, the invention may be embodied in different forms, and should not be construed as being limited to only the embodiments given herein. The above-mentioned embodiments are given to make the disclosure herein comprehensive and complete, so as to more fully convey the protection scope of the invention to those skilled in the art.

In this specification, terms such as “comprising” and “including” mean that in addition to the units and steps that are directly and explicitly stated in the specification and claims, the technical solution of the invention does not exclude the situation of other units and steps not directly or explicitly stated.

Terms such as “first” and “second” do not indicate the sequence of elements in terms of time, space, size, etc., but are only used to distinguish the elements unless otherwise specified.

According to some embodiments, the detection scheme of the motor parameters is implemented by receiving the first d-q axis feedback current corresponding to the injected first direct current signal and the first d-q axis voltage, the second d-q axis feedback current corresponding to the injected second direct current signal and the second d-q axis voltage and determining motor parameters based on the first d-q axis feedback current, the first d-q axis voltage, the second d-q axis feedback current and the second d-q axis voltage. By using two DC signals, the influence of the dead zone (time) of the inverter can be effectively avoided, thereby ensuring the accuracy of the motor parameters. This scheme uses the current closed-loop structure of vector control to avoid the risk of overcurrent, and does not require additional hardware equipment.

In addition, in some embodiments, both the first DC signal and the second DC signal are positive currents on the d-axis, which can effectively keep the rotor stationary (making the final measured motor parameters more accurate), and can avoid the risk of PMSM demagnetization.

Specific embodiments are further described below with reference to the accompanying drawings. It should be noted that, in order to describe the content related to the invention more clearly, some unnecessary features or circuit elements are not shown in the drawings. However, for those skilled in the art, this omission will not cause difficulty in implementing the technical solution described herein.

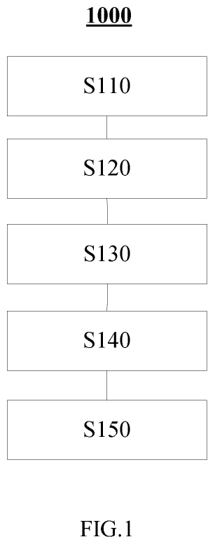

FIG. 1 shows a schematic flowchart of a method 1000 for detecting motor parameters. As shown in FIG. 1, the method 1000 includes the following steps:
in step 110, injecting a first direct current signal;
in step 120, receiving a first d-q axis feedback current corresponding to the first direct current signal and a first d-q axis voltage output by a current regulation module;
in step 130, injecting a second direct current signal different from the first direct current signal;
in step 140, receiving a second d-q axis feedback current corresponding to the second direct current signal and a second d-q axis voltage output by the current regulation module; and
in step 150, determining motor parameters based on the first d-q axis feedback current, the first d-q axis voltage, the second d-q axis feedback current and the second d-q axis voltage.

In the context of this application, the term “motor” may also be referred to as “electric motor”, which is a device that converts electrical energy into mechanical energy. It uses the energized coil (that is, the stator winding) to generate a rotating magnetic field and acts on the rotor to form a magneto-electric force rotation torque. In one or more embodiments, the motor may be a permanent magnet synchronous motor PMSM.

The term “motor parameters” is used to denote parameters related to vector control of the motor. In one embodiment, the motor parameters include: stator resistance, inductance, and permanent magnet flux linkage.

In step S110 and step S130, the first direct current signal and the second direct current signal are respectively injected. Here, both the first DC signal and the second DC signal are injected into the input side of the current closed-loop control structure of the motor. For example, see FIG. 3, which shows a schematic diagram of signal injection and parameter detection. As shown in FIG. 3, the current closed-loop control structure consists of a first mixer 312, a second mixer 314, a first PI controller 322, a second PI controller 324, a first coordinate system transformation module 330, and a space vector modulation module 340, an inverter module 350, and a second coordinate system transformation module 370. i_{dinj} represents the current injection signal of the d-axis, i_{qinj} represents the current injection signal of the q-axis, wherein i_{dinj} is applied to the first mixer 312 so as to be mixed with the d-axis feedback current i_{dfdb} output by the second coordinate system transformation module 370; similarly, i_{qinj} is applied to the second mixer 314 to be mixed with the q-axis feedback current i_{qfdb} output by the second coordinate system transformation module 370. The injected first/second direct current signal is to be understood as the sum of the d-axis current injection signal and the q-axis current injection signal.

In one or more embodiments, the “current regulation module” is a PI controller, also known as a proportional-integral controller. Of course, those skilled in the art can understand that the current regulation module can also be a PID controller.

Referring to FIG. 3, in the first time period, i_{dinj} and i_{qinj} (that is, components of the first DC signal on the d-axis and q-axis) are respectively injected into the input terminals of the first mixer 312 and the second mixer 314, thereby the first PI controller 322 outputting the first d-axis voltage Vd, the second PI controller 324 outputting the first q-axis voltage Vq, and the second coordinate system transformation module 370 outputting the first d-axis feedback current i_{dfdb} and the first q-axis feedback current i_{qfdb} and supplying them to the first mixer 312 and the second mixer 314 respectively. That is to say, the first d-axis voltage Vd and the first q-axis voltage Vq correspond to the injected first DC signal.

In the second time period (for example, the second time period is immediately after the first time period), a second DC signal different from the first DC signal (with different current vector values) is injected into the input terminals of the first mixer 312 and the second mixer 314. It should be noted that at this time i_{dinj} and i_{qinj} represent the components of the second DC signal on the d-axis and q-axis, so the first PI controller 322 outputs the second d-axis voltage Vd, the second PI controller 324 outputs the second q-axis voltage Vq, the second coordinate system transformation module 370 outputs the second d-axis feedback current i_{dfdb} and the second q-axis feedback current i_{qfdb}, and provides them to the first mixer 312 and the second mixer 314 respectively. That is to say, the second d-axis voltage Vd and the second q-axis voltage Vq correspond to the injected second direct current signal.

In one embodiment, both the first direct current signal and the second direct current signal are positive currents on the d-axis. That is to say, the component of the first DC signal and the second DC signal on the d-axis is positive DC, while the component on the q-axis is 0. This can effectively keep the rotor stationary (making the finally measured motor parameters more accurate), and can avoid the risk of demagnetization of the permanent magnet synchronous motor 360.

In step S150, motor parameters are determined based on the received first d-q axis feedback current, first d-q axis voltage, second d-q axis feedback current and second d-q axis voltage. In embodiments where both the first DC signal and the second DC signal are positive currents on the d-axis, the motor parameters may include stator resistance Rₛ, which may be determined, for example, according to the following equation:

$${R}_{s} = \frac{{V}_{dc 1} - {V}_{dc 2}}{{i}_{dc 1} - {i}_{dc 2}} ,$$

wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}.

After calculating the stator resistance Rₛ, in an embodiment, the permanent magnet flux linkage λₘ can be further calculated, wherein the permanent magnet flux linkage λₘ can be determined according to the following formula:

$${λ}_{m} = \frac{{V}_{rated} - {I}_{rated} * {R}_{s}}{2 * π * {f}_{rated}} ,$$

wherein V_{rated} is a rated (working) voltage of the permanent magnet synchronous motor, I_{rated} is a rated current of the permanent magnet synchronous motor, and f_{rated} is a rated frequency of the permanent magnet synchronous motor. Here, the rated voltage, rated current and rated frequency of the permanent magnet synchronous motor are all known quantities, for example, can be obtained from the nameplate of the permanent magnet synchronous motor.

Although not shown in FIG. 1, in one embodiment, the method 1000 may further include: injecting a third signal, the third signal is a sinusoidal signal with a certain frequency and amplitude applied on the d-axis; receiving a third d-axis voltage output by the current regulation module, the third d-axis voltage corresponding to the third signal; and determining a d-axis inductance L_{d} according to the third d-axis voltage.

In one embodiment, the third signal is represented by the following formula:

$${i}_{hd} = {i}_{d} + {i}_{h 1} sin ( 2 * π * {f}_{h 1} * t ) ,$$

wherein i_{hd} is the third signal, i_{d} is the DC bias on the d-axis (its magnitude is, for example, equal to the d-axis feedback current value i_{dc2} in the second d-q axis feedback current), iₕ₁ is an amplitude of the sinusoidal signal, and fₕ₁ is a frequency of the sinusoidal signal. In one embodiment, the frequency is 400-600 Hz, and this value range is a good balance between the detection accuracy of the motor parameters and the detection requirements of the digital controller—on the one hand, the frequency is much higher than the mechanical frequency (need to be as high as possible to avoid rotor rotation); on the other hand, the frequency takes into account the detection needs of the digital controller (in order to effectively restore the sine wave, the frequency cannot be too high).

Same as the first DC signal and the second DC signal, the third signal is also injected into the input side of the current closed-loop control structure of the motor. Since the third signal is only applied on the d-axis, its component on the q-axis is 0. For example, the d-axis component i_{dinj} injected into the first mixer 312 is equal to i_{hd}, while the i_{qinj} injected into the input terminal of the second mixer 314 is 0.

Continuing to refer to FIG. 3, during a third time period (for example, the third time period is immediately after the second time period), a third signal is injected into the input terminals of the first mixer 312 and the second mixer 314 (wherein, i_{dinj} is equal to i_{hd}, i_{qinj} is equal to 0), thus the first PI controller 322 outputs the third d-axis voltage V_{d}, the second PI controller 324 outputs the third q-axis voltage V_{q}, and the second coordinate system transformation module 370 outputs the third d-axis feedback current i_{dfdb} and the third q-axis feedback current i_{qfdb} and provides them to the first mixer 312 and the second mixer 314 respectively. That is, the third d-axis voltage V_{d} corresponds to the injected third signal.

In this embodiment, the d-axis inductance La is determined according to the following formula:

$${L}_{d} = \frac{{V}_{hd}}{2 * π * {f}_{h 1} * {i}_{h 1}} ,$$

wherein V_{hd} is the third d-axis voltage.

In one embodiment, the method 1000 further includes: injecting a fourth signal, the fourth signal is a sinusoidal signal with a certain frequency and amplitude applied on the q-axis; receiving the fourth q-axis voltage output by the current regulation module, which corresponds to the fourth signal; and determining the q-axis inductance L_{q} according to the fourth q-axis voltage.

In one embodiment, the fourth signal is represented by the following formula:

$${i}_{hq} = {i}_{h 2} sin ( 2 * π * {f}_{h 2} * t ) ,$$

wherein i_{hq} is the fourth signal, iₕ₂ is an amplitude of the sinusoidal signal, and fₕ₂ is a frequency of the sinusoidal signal. In one embodiment, the frequency is 400-600 Hz, and this value range is a good balance between the detection accuracy of the motor parameters and the detection requirements of the digital controller—on the one hand, the frequency is much higher than the mechanical frequency (the frequency needs to be as high as possible to avoid rotor rotation); on the other hand, the frequency takes into account the detection needs of the digital controller (in order to effectively restore the sine wave, the frequency cannot be too high).

Same as the first DC signal and the second DC signal, the fourth signal is also injected into the input side of the current closed-loop control structure of the motor. Since the fourth signal is only applied on the q-axis, its component on the d-axis is 0. For example, the d-axis component i_{dinj} injected into the first mixer 312 is equal to 0, while the i_{qinj} injected into the input terminal of the second mixer 314 is i_{hq}.

Continuing to refer to FIG. 3, during a fourth time period (for example, the fourth time period is immediately after the third time period), a fourth signal is injected into the input terminals of the first mixer 312 and the second mixer 314 (wherein, i_{dinj} is equal to 0, i_{qinj} is equal to i_{hq}), thus the first PI controller 322 outputs the fourth d-axis voltage V_{d}, the second PI controller 324 outputs the fourth q-axis voltage V_{q}, and the second coordinate system transformation module 370 outputs the fourth d-axis feedback current i_{dfdb} and the fourth q-axis feedback current i_{qfdb} and provides them to the first mixer 312 and the second mixer 314 respectively. That is, the fourth q-axis voltage V_{q} corresponds to the injected fourth signal.

In this embodiment, the q-axis inductance L_{q} is determined according to the following formula:

$${L}_{q} = \frac{{V}_{hq}}{2 * π * {f}_{h 2} * {i}_{h 2}} ,$$

wherein V_{hq} is the fourth q-axis voltage.

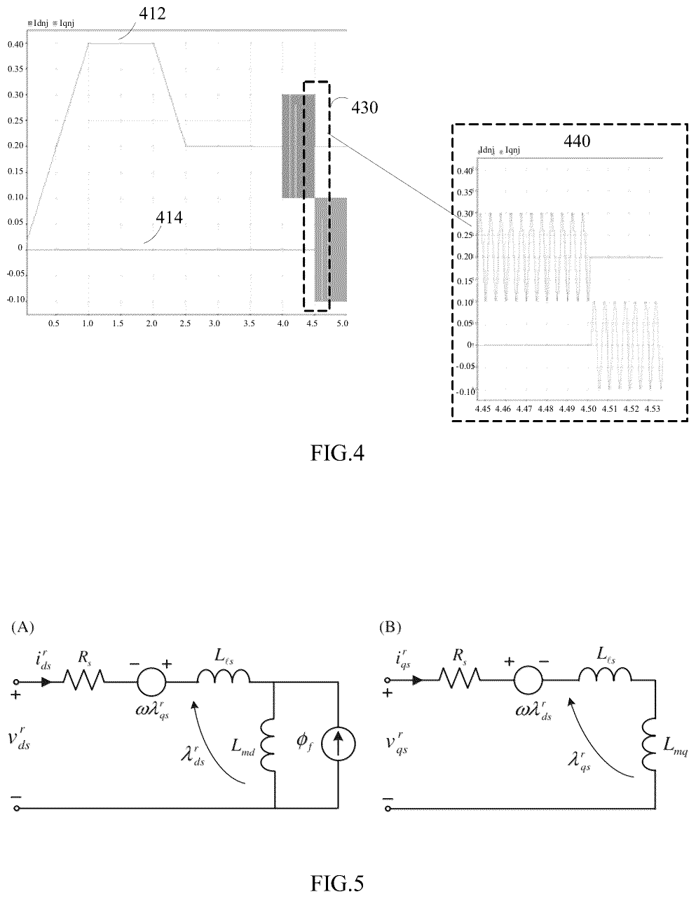

FIG. 4 shows a waveform diagram of signals injected into the d-q axis according to an embodiment of the invention, wherein the first DC signal, the second DC signal, the third signal and the fourth signal are injected onto the d-q axis in sequence. As shown in FIG. 4, reference numeral 412 represents the component of the injected current signal on the d-axis, namely i_{dinj}, and reference numeral 414 represents the component of the injected current signal on the q-axis, namely i_{qinj}. In FIG. 4, reference numeral 440 shows an enlarged view of the component on the d-axis and the component on the q-axis of the injected current signal framed by the dotted box 430. It can be seen from the enlarged part that a sine wave (i.e., the third signal) is first injected on the d-axis, and then a sine wave (i.e., the fourth signal) is injected on the q-axis.

In addition, those skilled in the art can easily understand that the method 1000 provided by the foregoing one or more embodiments can be implemented by a computer program. For example, the computer program is included in a computer program product, and when the computer program is executed by a processor, the motor parameter detection method 1000 of one or more embodiments is implemented. For another example, when the computer storage medium (such as a USB flash drive) storing the computer program is connected to the computer, running the computer program can execute the motor parameter detection method 1000 of one or more embodiments of the invention.

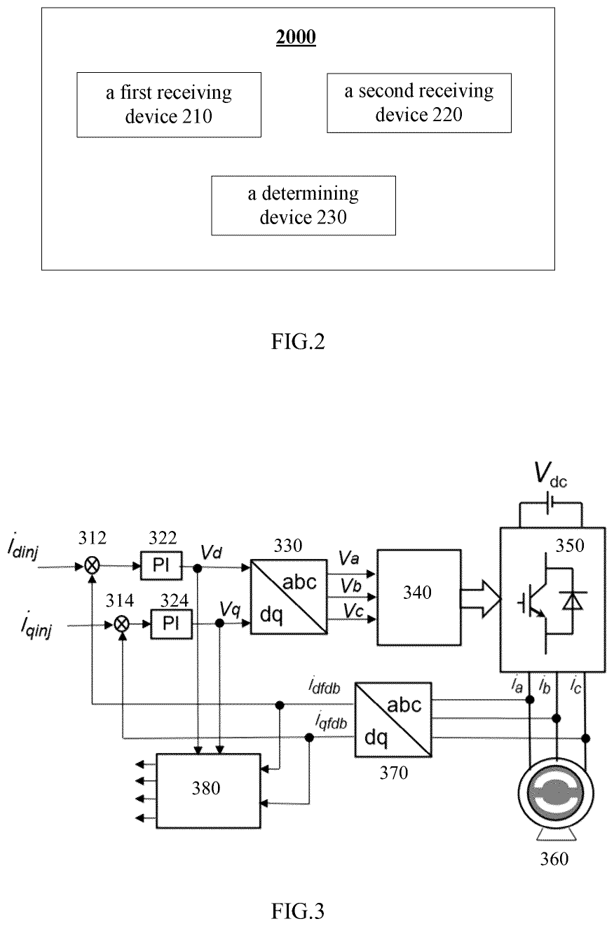

FIG. 2 shows a schematic structural diagram of an apparatus for detecting motor parameters 2000. As shown in FIG. 2, the apparatus 2000 includes: a first receiving device 210, a second receiving device 220, and a determining device 230, wherein the first receiving device 210 is used for receiving a first d-q axis feedback current corresponding to an injected first direct current signal and a first d-q axis voltage output by a current regulation module; the second receiving device 220 is used for receiving a second d-q axis feedback current corresponding to an injected second direct current signal and a second d-q axis voltage output by the current regulation module; and the determining device 230 is used for determining the motor parameters based on the first d-q axis feedback current, the first d-q axis voltage, the second d-q axis feedback current and the second d-q axis voltage.

In one embodiment, the motor is a permanent magnet synchronous motor PMSM, the current regulation module is a PI controller, and both the first DC signal and the second DC signal are positive currents on the d-axis.

For example, continuing to refer to FIG. 3, the motor 360 is a permanent magnet synchronous motor PMSM, and an apparatus for detecting motor parameters is denoted by reference numeral 380. The detection apparatus 380 receives the output d-axis feedback current i_{dfdb} and q-axis feedback current i_{qfdb} from the second coordinate system transformation module 370, and also receives the d-axis voltage V_{d} from the first PI controller 322, receives the q-axis voltage V_{q} from the second PI controller 324, and then obtain one or more motor parameters.

In one embodiment, the motor parameters include stator resistance Rₛ. In this embodiment, the determining device 230 is configured to determine the stator resistance Rₛ according to the following equation:

$${R}_{s} = \frac{{V}_{dc 1} - {V}_{dc 2}}{{i}_{dc 1} - {i}_{dc 2}} ,$$

wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}.

In an embodiment, the motor parameters include the permanent magnet flux linkage λₘ and the determining device 230 is configured to determine the permanent magnet flux linkage λₘ according to the following formula:

$${λ}_{m} = \frac{{V}_{rated} - {I}_{rated} * {R}_{s}}{2 * π * {f}_{rated}} ,$$

wherein V_{rated} is a rated voltage of the permanent magnet synchronous motor, I_{rated} is a rated current of the permanent magnet synchronous motor, and f_{rated} is a rated frequency of the permanent magnet synchronous motor.

Although not shown in FIG. 2, in one embodiment, the apparatus 2000 may further include: a third receiving device for receiving the third d-axis voltage output by the current regulation module, the third d-axis voltage corresponding to the injected third signal, and the third signal is a sinusoidal signal with a certain frequency and amplitude applied on the d-axis. The determining device 230 is further configured to determine a d-axis inductance L_{d} according to the third d-axis voltage.

In one embodiment, the third signal is represented by the following formula:

$${i}_{hd} = {i}_{d} + {i}_{h 1} sin ( 2 * π * {f}_{h 1} * t ) ,$$

wherein i_{hd} is the third signal, i_{d} is the DC bias on the d-axis, in is an amplitude of the sinusoidal signal, and fₕ₁ is a frequency of the sinusoidal signal.

In this way, the determining device 230 is configured to determine the d-axis inductance L_{d} according to the following formula:

$${L}_{d} = \frac{{V}_{hd}}{2 * π * {f}_{h 1} * {i}_{h 1}} ,$$

wherein V_{hd} is the third d-axis voltage.

In one embodiment, the apparatus 2000 further includes: a fourth receiving device for receiving a fourth q-axis voltage output by the current regulation module, the fourth q-axis voltage being corresponding to an injected fourth signal which is a sinusoidal signal with a certain frequency and amplitude applied on the q-axis; and the determining device 230 is further configured to determine the q-axis inductance L_{q} according to the fourth q-axis voltage.

In one embodiment, the fourth signal is represented by the following formula:

$${i}_{hq} = {i}_{h 2} sin ( 2 * π * {f}_{h 2} * t ) ,$$

wherein i_{hq} is the fourth signal, iₕ₂ is an amplitude of the sinusoidal signal, and fₕ₂ is a frequency of the sinusoidal signal. In this way, the determining device 230 is configured to determine the q-axis inductance L_{q} according to the following formula:

$${L}_{q} = \frac{{V}_{hq}}{2 * π * {f}_{h 2} * {i}_{h 2}} ,$$

wherein V_{hq} is the fourth q-axis voltage.

The above apparatus for detecting motor parameters 2000 can be applied to various motor systems, including but not limited to air conditioner compressor systems. In one embodiment, the air conditioner compressor system includes: a permanent magnet synchronous motor; and an apparatus for detecting motor parameters 2000, wherein the detection apparatus 2000 is used for detecting the motor parameters of the permanent magnet synchronous motor.

In the context of this invention, a number of motor parameter calculation formulas are provided. In one or more embodiments, these calculation formulas can be derived based on the d-q axis equivalent circuit model of the permanent magnet synchronous motor as shown in FIG. 5. In FIG. 5, the circuit diagram of the left half shows the equivalent circuit of the d-axis, and the circuit diagram of the right half shows the equivalent circuit of the q-axis. As shown in FIG. 5, for example, in the d-axis equivalent circuit, the stator resistance Rₛ is coupled in series with the counter electromotive force ωλ_{ds}^{r} and the leakage inductance Lₗₛ. Similarly, in the q-axis equivalent circuit, the stator resistance Rₛ is coupled in series with the counter electromotive force ωλ_{ds}^{r} and the leakage inductance Lₗₛ. Those skilled in the art can understand that the sum of the leakage inductance Lₗₛ and the d-axis excitation inductance L_{md} is the d-axis inductance L_{d}. Similarly, the sum of the leakage inductance Lₗₛ and the q-axis excitation inductance L_{mq} is the q-axis inductance L_{q}.

The above examples mainly illustrate the technical solutions of one or more embodiments of the invention. Although only some of the embodiments of the invention have been described, those skilled in the art should understand that the invention can be implemented in many other forms without departing from the gist and scope thereof. Therefore, the shown examples and embodiments are to be regarded as illustrative rather than restrictive, and the invention may cover various modifications and substitutions without departing from the spirit and scope of the invention as defined in the claims.

The invention claimed is:

1. A method for detecting motor parameters, characterized by comprising:
injecting a first direct current signal;
receiving a first d-q axis feedback current corresponding to the first direct current signal and a first d-q axis voltage output by a current regulation module;
injecting a second direct current signal different from the first direct current signal;
receiving a second d-q axis feedback current corresponding to the second direct current signal and a second d-q axis voltage output by the current regulation module; and
determining motor parameters based on the first d-q axis feedback current, the first d-q axis voltage, the second d-q axis feedback current and the second d-q axis voltage.

2. The method of claim 1, wherein the motor is a permanent magnet synchronous motor and the current regulation module is a PI controller.

3. The method of claim 2, wherein both the first direct current signal and the second direct current signal are positive currents on the d-axis.

4. The method of claim 3, wherein the motor parameters include a stator resistance Rₛ, wherein the stator resistance Rₛ is determined according to the following formula:
$${R}_{s} = \frac{{V}_{dc 1} - {V}_{dc 2}}{{i}_{dc 1} - {i}_{dc 2}} ,$$
wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}.

5. The method of claim 4, wherein the motor parameters include permanent magnet flux linkage λₘ, wherein the permanent magnet flux linkage λₘ is determined according to the following formula:
$${λ}_{m} = \frac{{V}_{rated} - {I}_{rated} * {R}_{s}}{2 * π * {f}_{rated}} ,$$
wherein V_{rated} is a rated voltage of the permanent magnet synchronous motor, I_{rated} is a rated current of the permanent magnet synchronous motor, and f_{rated} is a rated frequency of the permanent magnet synchronous motor.

6. The method of claim 5, further comprising:
injecting a third signal, the third signal being a sinusoidal signal with a certain frequency and amplitude applied on the d-axis;
receiving a third d-axis voltage output by the current regulation module, the third d-axis voltage being corresponding to the third signal; and
determining a d-axis inductance La according to the third d-axis voltage.

7. The method of claim 6, wherein the third signal is represented by the following formula:
$${i}_{hd} = {i}_{d} + {i}_{h 1} sin ( 2 * π * {f}_{h 1} * t ) ,$$
wherein i_{hd} is the third signal, i_{d} is a DC offset on the d-axis, iₕ₁ is an amplitude of the sinusoidal signal, and fₕ₁ is a frequency of the sinusoidal signal.

8. The method of claim 7, wherein the d-axis inductance La is determined according to the following formula:
$${L}_{d} = \frac{{V}_{hd}}{2 * π * {f}_{h 1} * {i}_{h 1}} ,$$
wherein V_{hd} is the third d-axis voltage.

9. The method of claim 6, further comprising:
injecting a fourth signal, the fourth signal being a sinusoidal signal with a certain frequency and amplitude applied on the q-axis;
receiving a fourth q-axis voltage output by the current regulation module, the fourth q-axis voltage being corresponding to the fourth signal; and
determining a q-axis inductance L_{q} according to the fourth q-axis voltage,
wherein the fourth signal is represented by the following formula:
$${i}_{hq} = {i}_{h 2} sin ( 2 * π * {f}_{h 2} * t ) ,$$
wherein i_{hq} is the fourth signal, iₕ₂ is an amplitude of the sinusoidal signal, and fₕ₂ is a frequency of the sinusoidal signal,
wherein the q-axis inductance L_{q} is determined according to the following formula:
$${L}_{q} = \frac{{V}_{hq}}{2 * π * {f}_{h 2} * {i}_{h 2}} ,$$
wherein V_{hq} is the fourth q-axis voltage.

10. A apparatus for detecting motor parameters, comprising:
a first receiving device for receiving a first d-q axis feedback current corresponding to an injected first direct current signal and a first d-q axis voltage output by a current regulation module;
a second receiving device for receiving a second d-q axis feedback current corresponding to an injected second direct current signal and a second d-q axis voltage output by the current regulation module; and
a determining device for determining the motor parameters based on the first d-q axis feedback current, the first d-q axis voltage, the second d-q axis feedback current and the second d-q axis voltage.

11. The apparatus of claim 10, wherein the motor is a permanent magnet synchronous motor and the current regulation module is a PI controller, and both the first direct current signal and the second direct current signal are positive currents on the d-axis.

12. The apparatus of claim 11, wherein the motor parameters include a stator resistance Rₛ, wherein the determining device is configured to determine the stator resistance Rₛ according to the following formula:
$${R}_{s} = \frac{{V}_{dc 1} - {V}_{dc 2}}{{i}_{dc 1} - {i}_{dc 2}} ,$$
wherein V_{dc1} is a d-axis voltage in the first d-q axis voltage, V_{dc2} is a d-axis voltage in the second d-q axis voltage, i_{dc1} is a d-axis feedback current value in the first d-q axis feedback current, and i_{dc2} is a d-axis feedback current value in the second d-q axis feedback current, and i_{dc1}>i_{dc2}.

13. The apparatus of claim 12, wherein the motor parameters include permanent magnet flux linkage λₘ, wherein the determining device is configured to determine the permanent magnet flux linkage λₘ according to the following formula:
$${λ}_{m} = \frac{{V}_{rated} - {I}_{rated} * {R}_{s}}{2 * π * {f}_{rated}} ,$$
wherein V_{rated} is a rated voltage of the permanent magnet synchronous motor, I_{rated} is a rated current of the permanent magnet synchronous motor, and f_{rated} is a rated frequency of the permanent magnet synchronous motor.

14. The apparatus of claim 13, further comprising:
a third receiving device for receiving a third d-axis voltage output by the current regulation module, the third d-axis voltage being corresponding to the third signal which is a sinusoidal signal with a certain frequency and amplitude applied on the d-axis; and
the determining device is also configured to determine a d-axis inductance La according to the third d-axis voltage.

15. The apparatus of claim 14, wherein the third signal is represented by the following formula:
$${i}_{hd} = {i}_{d} + {i}_{h 1} sin ( 2 * π * {f}_{h 1} * t ) ,$$
wherein i_{hd} is the third signal, i_{d} is a DC offset on the d-axis, in is an amplitude of the sinusoidal signal, and fₕ₁ is a frequency of the sinusoidal signal, and
wherein the determining device is further configured to determine the d-axis inductance L_{d} according to the following formula:
$${L}_{d} = \frac{{V}_{hd}}{2 * π * {f}_{h 1} * {i}_{h 1}} ,$$
wherein V_{hd} is the third d-axis voltage.

16. The apparatus of claim 14, further comprising:
a fourth receiving device for receiving a fourth q-axis voltage output by the current regulation module, the fourth q-axis voltage being corresponding to an injected fourth signal which is a sinusoidal signal with a certain frequency and amplitude applied on the q-axis; and
the determining device is further configured to determine a q-axis inductance L_{q} according to the fourth q-axis voltage,
wherein the fourth signal is represented by the following formula:
$${i}_{hq} = {i}_{h 2} sin ( 2 * π * {f}_{h 2} * t ) ,$$
wherein i_{hq} is the fourth signal, iₕ₂ is an amplitude of the sinusoidal signal, and fₕ₂ is a frequency of the sinusoidal signal,
wherein the q-axis inductance L_{q} is determined according to the following formula:
$${L}_{q} = \frac{{V}_{hq}}{2 * π * {f}_{h 2} * {i}_{h 2}} ,$$
wherein V_{hq} is the fourth q-axis voltage.

17. An air-conditioning compressor system, characterized by comprising:
a permanent magnet synchronous motor; and
the apparatus according to claim 10, for detecting motor parameters of the permanent magnet synchronous motor.
